(19) United States
(12) Patent Application Publication
(10) Pub. No.: US 2017/0235200 A1
(43) Pub. Date: Aug. 17, 2017

(54) DISPLAY DEVICE AND MANUFACTURING METHOD THEREOF

(71) Applicant: Samsung Display Co., Ltd., Yongin-si (KR)

(72) Inventors: Joonggun CHONG, Yongin-si (KR); Taekyung YIM, Seoul (KR); Jangil KIM, Asan-si (KR); Suwan WOO, Osan-si (KR); Yeogeon YOON, Suwon-si (KR)

(21) Appl. No.: 15/382,171

(22) Filed: Dec. 16, 2016

(30) Foreign Application Priority Data
Feb. 17, 2016 (KR) 10-2016-0018473

(51) Int. Cl. G02F 1/1362; H01L 29/786; H01L 27/12; G02F 1/1368; G02F 1/1343

(52) U.S. Cl. CPC G02F 1/136286; G02F 1/1368; G02F 1/136209; G02F 1/134309; H01L 27/1222; H01L 27/124; H01L 29/78666; H01L 29/78633; G02F 2001/136222; G02F 2201/123; G02F 2001/136218

(57) ABSTRACT

A display device includes: a substrate; a data line disposed on the substrate, the data line extending in a first direction; a gate insulating layer disposed on the data line; a gate line disposed on the gate insulating layer, the gate line extending in a second direction intersecting the first direction; a gate electrode protruding from the gate line; a thin film transistor connected to the gate line and the data line; and a first shielding electrode disposed on the same layer as a layer on which the gate line is disposed, the first shielding electrode overlapping the data line.

This application claims priority to Korean Patent Application No. 10-2016-0018473, filed on Feb. 17, 2016, and all the benefits accruing therefrom under 35 U.S.C. §119, the content of which in their entirety is herein incorporated by reference.

### BACKGROUND

1. Field

Exemplary embodiments of the inventive concept relate to a display device and a method of manufacturing the display device, and more particularly, to a display device improved in terms of an aperture ratio and a method of manufacturing the display device.

2. Description of the Related Art

Display devices are classified into liquid crystal display (LCD) devices, organic light emitting diode (OLED) display devices, plasma display panel (PDP) devices, electrophoretic display (EPD) devices, and the like, based on a light emitting scheme thereof.

Among the types of the display devices, an LCD device includes two substrates disposed to oppose one another, an electrode disposed on at least one of the two substrates, and a liquid crystal layer between the two substrates.

A typical type of the LCD device includes a plurality of thin film transistors and a pixel electrode disposed on one of the two substrates and a plurality of color filters, a light blocking unit, and a common electrode disposed on the other of the two substrates. However, in recent times, a color-filter on array (COA) structure is being applied to the LCD device, in which the color filter, the light blocking unit, and the pixel electrode, except the common electrode, are disposed on a substrate.

In addition, in recent times, in order to secure an aperture ratio of a pixel, the pixel electrode and a data line are disposed to be adjacent to each other or to overlap each other. In such an example, a parasitic capacitance is formed between the pixel electrode and the data line which applies a voltage that varies continuously, and defects may occur due to the parasitic capacitance.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Exemplary embodiments of the inventive concept are directed to a display device that includes a shielding electrode configured to reduce a parasitic capacitance and to a method of manufacturing the display device.

According to an exemplary embodiment of the inventive concept, a display device includes: a substrate; a data line disposed on the substrate, the data line extending in a first direction; a gate insulating layer disposed on the data line; a gate line disposed on the gate insulating layer, the gate line extending in a second direction intersecting the first direction; a gate electrode protruding from the gate line; a thin film transistor connected to the gate line and the data line; and a first shielding electrode disposed on the same layer as a layer on which the gate line is disposed, the first shielding electrode overlapping the data line.

The first shielding electrode may include the same material as a material included in the gate line.

The first shielding electrode may have a greater width than a width of the data line.

The first shielding electrode may completely cover the data line in a plan view.

The thin film transistor may include: a source electrode on the substrate, the source electrode extending from the data line; a drain electrode spaced apart from the source electrode; and a semiconductor layer disposed between the source electrode and the drain electrode.

The semiconductor layer may overlap at least a portion of upper surfaces of the source electrode and the drain electrode.

The source electrode and the drain electrode may be disposed on the semiconductor layer and overlap at least a portion of the semiconductor layer.

The display device may further include an ohmic contact layer disposed between the semiconductor layer and the source electrode or between the semiconductor and the drain electrode.

The display device may further include a light blocking pattern disposed between the semiconductor layer and the substrate.

The display device may further include a color filter on the gate insulating layer.

The color filter may be disposed between the gate insulating layer and the gate electrode.

The color filter may be disposed on the gate electrode.

The display device may further include a pixel electrode connected to the thin film transistor. An end portion of the first shielding electrode may overlap the pixel electrode.

The display device may further include a second shielding electrode disposed on the same layer as a layer on which the pixel electrode is disposed, the second shielding electrode overlapping the gate line.

The second shielding electrode may include the same material as that included in the pixel electrode.

The second shielding electrode may have a greater width than a width of the gate line.

According to an exemplary embodiment of the inventive concept, a display device includes: a substrate; a data line disposed on the substrate, the data line extending in a first direction; a source electrode and a drain electrode disposed on the substrate; a semiconductor layer disposed on the source electrode and the drain electrode to overlap the source electrode and the drain electrode; a gate insulating layer disposed on the semiconductor layer; a gate line disposed on the gate insulating layer, the gate line extending in a second direction intersecting the first direction; a first shielding electrode disposed on the gate insulating layer, the first shielding electrode overlapping the data line and being disposed on the same layer as the gate line and being formed of the same material as the gate line; and a pixel electrode connected to the drain electrode.

The display device may further include a color filter disposed between the gate line and the gate insulating layer.

The display device may further include a color filter disposed between the gate line and the pixel electrode.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure of inventive concept will be more clearly understood from the following detailed description taken in conjunction with the accompanying drawings, in which:

FIG. 1 is a schematic view illustrating pixels included in a first panel;

FIG. 2 is a plan view illustrating one of pixels illustrated in FIG. 1;

FIG. 3 is a cross-sectional view of an exemplary embodiment taken along line I-I′ of FIG. 2;

FIG. 4 is a cross-sectional view of another exemplary embodiment taken along line I-I′ of FIG. 2;

FIG. 5 is a cross-sectional view of an exemplary embodiment taken along line II-II′ of FIG. 2; and

FIG. 6 is a cross-sectional view of still another exemplary embodiment taken along line I-I′ of FIG. 2

### DETAILED DESCRIPTION

Exemplary embodiments will now be described more fully hereinafter with reference to the accompanying drawings. Although the inventive concept can be modified in various manners and have several embodiments, exemplary embodiments are illustrated in the accompanying drawings and will be mainly described in the specification. However, the scope of the inventive concept is not limited to the exemplary embodiments and should be construed as including all the changes, equivalents, and substitutions included in the spirit and scope of the inventive concept.

In the drawings, certain elements or shapes may be illustrated in an enlarged manner or in a simplified manner to better illustrate the inventive concept, and other elements present in an actual product may also be omitted. Thus, the drawings are intended to facilitate the understanding of the present inventive concept.

When a layer, area, or plate is referred to as being “on” another layer, area, or plate, it may be directly on the other layer, area, or plate, or intervening layers, areas, or plates may be present therebetween. Conversely, when a layer, area, or plate is referred to as being “directly on” another layer, area, or plate, intervening layers, areas, or plates may be absent therebetween. Further when a layer, area, or plate is referred to as being “below” another layer, area, or plate, it may be directly below the other layer, area, or plate, or intervening layers, areas, or plates may be present therebetween. Conversely, when a layer, area, or plate is referred to as being “directly below” another layer, area, or plate, intervening layers, areas, or plates may be absent therebetween.

The spatially relative terms “below”, “beneath”, “less”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms used herein (including technical and scientific terms) have the same meaning as commonly understood by those skilled in the art to which this inventive concept pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Exemplary embodiments of a display device are described under the assumption that the display device is a liquid crystal display (LCD) device, but the exemplary embodiments may be applied to an organic electroluminescence display device.

In addition, the exemplary embodiments of the display device have a color filter on array (COA) structure in which a thin film transistor and a color filter are disposed on the same substrate, but the exemplary embodiments are not limited thereto.

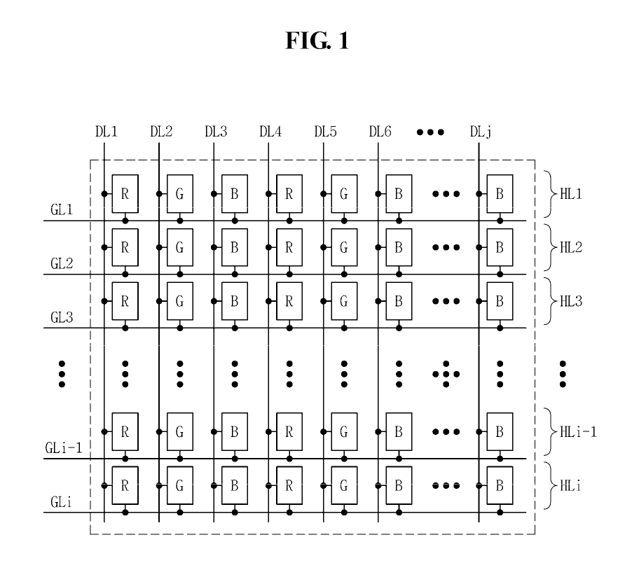

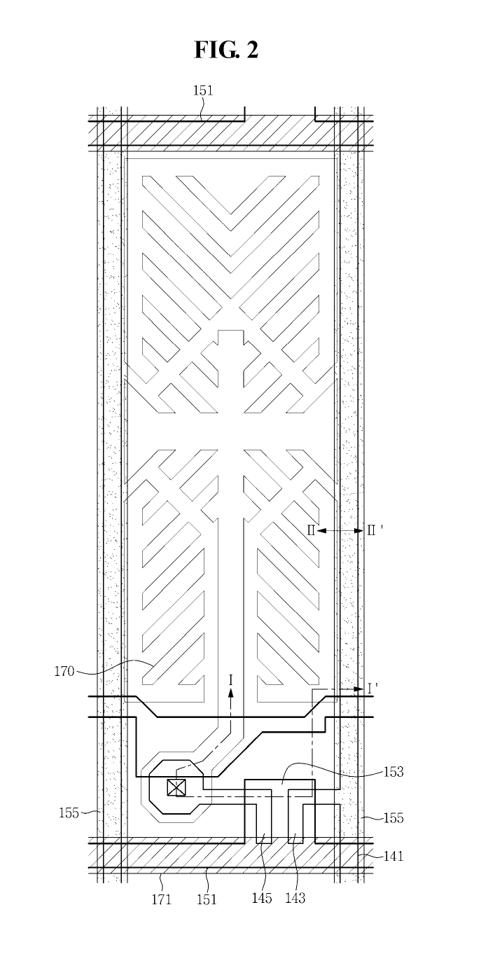

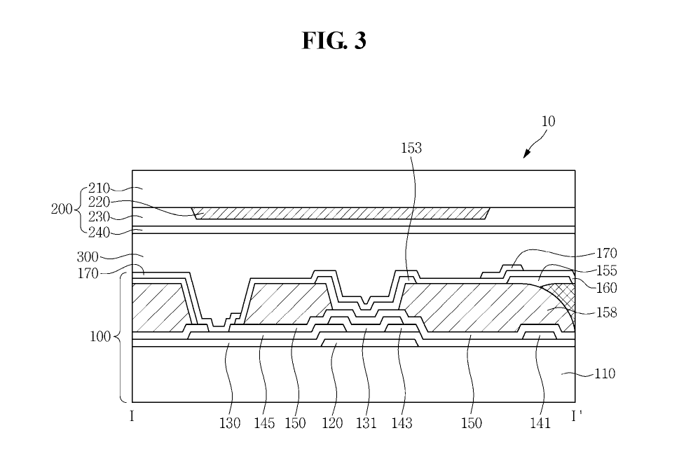

FIG. 1 is a schematic view illustrating pixels included in a first panel 100; FIG. 2 is a plan view illustrating one of pixels illustrated in FIG. 1; and FIG. 3 is a cross-sectional view of an exemplary embodiment taken along line I-I′ of FIG. 2.

Referring to FIGS. 1 and 3, an exemplary embodiment of a display device 10 includes the first panel 100 and a second panel 200 that oppose each other, and a liquid crystal layer 300 between the first panel 100 and the second panel 200.

Referring to FIG. 1, the first panel 100 includes a plurality of pixels R, G, and B. As illustrated in FIG. 1, the pixels R, G, and B are disposed in a display area of the first panel 100.

The pixels R, G, and B are arranged in a matrix form. The pixels R, G, and B are classified into red pixels R displaying a red image, green pixels G displaying a green image, and blue pixels B displaying a blue image. In such an exemplary embodiment, the red pixel R, the green pixel G, and the blue pixel B that are adjacently disposed in a horizontal direction may define a unit pixel for displaying a unit image.

There are “j” number of pixels arranged along an n^{th} (n is a number selected from 1 to i) horizontal line (hereinafter, n^{th} horizontal line pixels), and the n^{th} horizontal line pixels are connected to first to j^{th} data lines DL1 to DLj, respectively. Further, the n^{th} horizontal line pixels are connected to an n^{th} gate line together. Accordingly, the n^{th} horizontal line pixels receive an n^{th} gate signal as a common signal. That is, “j” number of pixels arranged in the same horizontal line receive the same gate signal, while pixels arranged in different horizontal lines receive different gate signals, respectively. For example, each of the red pixel R and the green pixel G on the first horizontal line HL1 receives a first gate signal, while the red pixel R and the green pixel G on the second horizontal line HL2 receive a second gate signal that has a different timing from that of the first gate signal.

According to an exemplary embodiment, as illustrated in FIGS. 2 and 3, the first panel 100 includes a first substrate 110, a light blocking pattern 120, a first insulating layer 130, a data line 141, a source electrode 143, a drain electrode 145, a semiconductor layer 131, a gate insulating layer 150, a color filter 158, gate wirings 151 and 153, a second insulating layer 160, and a pixel electrode 170.

The first substrate 110 may be an insulating substrate, such as a plastic substrate, which has light transmitting characteristics and flexibility. However, the first exemplary embodiment is not limited thereto, and the first substrate 110 may include a hard substrate such as a glass substrate. That is, the first substrate 110 may include plastic or transparent glass such as soda lime glass or borosilicate glass, for example.

As illustrated in FIG. 3, the light blocking pattern 120 is disposed on the first substrate 110 and is configured to block light incident to a thin film transistor. The light blocking pattern 120 is disposed under the semiconductor layer 131 to overlap the semiconductor layer 131. The light blocking pattern 120 may completely cover the semiconductor layer 131.

The light blocking pattern 120 may include a material that may absorb and block light. For example, the light blocking pattern 120 may include amorphous silicon or amorphous germanium, for example.

The first insulating layer 130 is disposed on the first substrate 110 on the light blocking pattern 120 and prevents permeation of external moisture or humidity. The first insulating layer 130 may have a monolayer structure or a multilayer structure including, for example, silicon oxides, silicon nitrides, a photosensitive organic material, or a low dielectric constant insulating material such as a-Si:C:O or a-Si:O:F.

Data wirings 141, 143, and 145 are disposed on the first insulating layer 130. The data wirings 141, 143, and 145 include a data line 141 that is formed in a first direction, e.g., a longitudinal direction, in a plan view and defines a pixel unit along with a gate line 151, a source electrode 143 that branches off from the data line 141, is disposed below the semiconductor layer, and extends to overlap the semiconductor layer 131, and a drain electrode 145 that is spaced apart from the source electrode 143 and opposes the source electrode 143 with respect to a gate electrode 153 or a channel area of the thin film transistor.

The data line 141 sequentially outputs a data voltage in response to a data control signal externally applied thereto. The data voltages having polarities varying with every frame period are alternately input to each data line 141 or the data voltages having different polarities are respectively input to adjacent ones of the data lines 141 in the same frame.

The drain electrode 145 disposed below the semiconductor layer may extend to overlap the pixel electrode 170. The data wirings 141, 143, and 145 may be simultaneously formed in the same process.

The semiconductor layer 131 is disposed on the first insulating layer 130, the source electrode 143, and the drain electrode 145 and a channel region is formed between the source electrode 143 and the drain electrode 145. In such an exemplary embodiment, according to an exemplary embodiment, the semiconductor layer 131 is also disposed on the source electrode 143 and the drain electrode 145 to overlap the source electrode 143 and the drain electrode 145. That is, the semiconductor layer 131 overlaps a portion of upper surfaces of the source electrode 143 and the drain electrode 145. The semiconductor layer 131 may include amorphous silicon (hereinafter, a-Si) or an oxide semiconductor including at least one selected from: gallium (Ga), indium (In), tin (Sn), and zinc (Zn).

In addition, an ohmic contact layer (not illustrated) may be disposed between the semiconductor layer 131 and the source electrode 143 and/or the drain electrode 145. The ohmic contact layer is configured to improve contact properties between the semiconductor layer 131 and the source electrode 143 and/or the drain electrode 145.

Herein, the ohmic contact layer may include amorphous silicon doped with n-type impurities at high concentration (n+a-Si). In the case that the contact properties between the semiconductor layer 131 and the source electrode 143 and/or the drain electrode 145 is secured sufficiently without the ohmic contact layer, the ohmic contact layer according to an exemplary embodiment may be omitted.

The gate insulating layer 150 is disposed on the first substrate 110, the data wirings 141, 143, and 145, and the semiconductor layer 131. The gate insulating layer 140 may include silicon oxides (SiOx) or silicon nitrides (SiNx). In addition, the gate insulating layer 150 may further include aluminum oxides, titanium oxides, tantalum oxides, or zirconium oxides.

The color filter 158 is disposed on the gate insulating layer 150. The color filter 158 may be one selected from a group consisting of a red color filter, a green color filter, a blue color filter, a cyan color filter, a magenta color filter, and a white color filter.

According to an exemplary embodiment, the color filter 158 is disposed between the gate insulating layer 150 and the gate electrode 153. In addition, the color filter 158 is disposed between the gate insulating layer 150 and a first shielding electrode 155 to be described below.

The color filter 158 extends along a direction and is disposed on the first substrate 110. For example, the color filter 158 has a linear shape in a plan view and extends along the first direction, that is, the longitudinal direction of the drawings. In addition, adjacent ones of the color filters 158 that are adjacent in a transverse direction in the drawings may overlap each another at border areas therebetween.

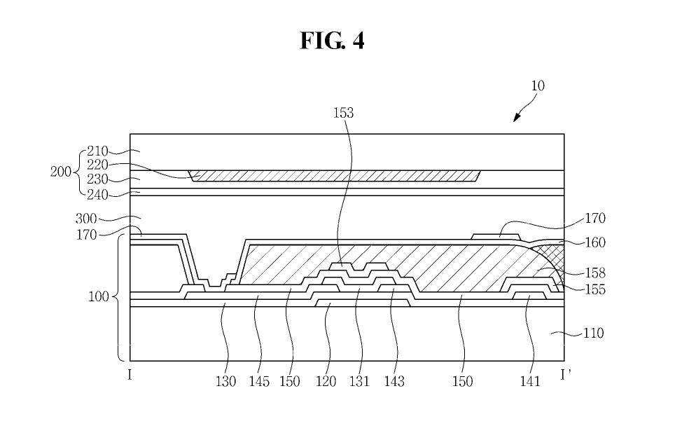

FIG. 4 is a cross-sectional view of another exemplary embodiment taken along line I-I′ of FIG. 2.

Referring to FIG. 4, a color filter 158 is disposed on a gate insulating layer 150 and a gate electrode 153. In addition, the color filter 158 is disposed on a first shielding electrode 155.

The color filter 158 extends along a direction and is disposed on a first substrate 110. For example, the color filter 158 has a linear shape in a plan view and extends along a first direction, that is, a longitudinal direction of the drawings. In addition, adjacent ones of the color filters 158 that are adjacent in a transverse direction in the drawings may overlap each another at border areas therebetween.

Referring to FIGS. 2 and 3, gate wirings 151 and 153 are disposed on the gate insulating layer 150 and transmit a gate signal. The gate wirings 151 and 153 include a gate line 151 and the gate electrode 153.

The gate line 151 extends in a second direction that intersects a data line 141 extending in the first direction. For example, the gate line 151 extends in a transverse direction in the drawings. The gate line 151 sequentially outputs gate signals in response to a gate control signal externally applied thereto. The gate signal includes a gate-on voltage Von that may turn on thin film transistors connected to a selected one of the gate lines 151 and a gate-off voltage Voff that may turn off thin film transistors connected to an unselected one of the gate lines 151. The gate electrode 153 protrudes from the gate line 151 to form a protrusion. The gate electrode 153, along with a source electrode 143 and a drain electrode 145, forms three terminals of the thin film transistor.

In addition, the gate electrode 153 is formed on the color filter 158 in a region corresponding to a hole formed through the color filter 158 and is disposed on the gate insulating layer 150 to overlap at least a portion of the semiconductor layer 131. That is, the color filter 158 has a hole exposing the gate insulating layer 150 and the gate electrode 153 is formed to cover the hole formed through the color filter 158.

The gate wirings 151 and 153 may include or be formed of an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), titanium (Ti), tantalum (Ta), or the like.

In addition, the gate wirings 151 and 153 may have a multilayer structure including two conductive layers (not illustrated) having different physical properties.

For example, one of the two conductive layers may include a metal having low resistivity so as to reduce a signal delay or voltage drop, for example, an aluminum (Al)-based metal, a silver (Ag)-based metal, a copper (Cu)-based metal, for example.

On the other hand, the other of the two conductive layers may include a material that has excellent contact characteristics with indium tin oxide (ITO) and indium zinc oxide (IZO), for example. Examples of such a material may include a molybdenum-based metal, chromium, titanium, and tantalum.

Examples of the multi-layer structure may include: a chromium (Cr) lower layer and an aluminum (Al) upper layer; an aluminum (Al) lower layer and a molybdenum (Mo) upper layer; and a titanium (Ti) lower layer and a copper (Cu) upper layer. However, exemplary embodiments are not limited thereto, and the gate wirings 151 and 153 may include or be formed of various metals and conductors.

A structure of the thin film transistor is illustrated in FIGS. 2 and 3 by way of example, but may be modified into various structures. That is, the structure of the thin film transistor is not limited to the exemplary embodiments and may be modified into various structures including a bottom gate thin film transistor.

The first shielding electrode 155 is disposed on the same layer as a layer on which the gate line 151 is disposed and overlaps the data line 141. For example, the first shielding electrode 155 is disposed on the gate insulating layer 150 to be spaced apart from the gate line 151 and extends substantially parallel to the data line 141. In addition, the first shielding electrode 155 overlaps the data line 141 so that a parasitic capacitance generated between the pixel electrode 170 and the data line 141, which may overlap the pixel electrode 170, may be significantly reduced.

The first shielding electrode 155 may have a greater width than that of the data line 141. In such an exemplary embodiment, an end portion of the first shielding electrode 155 may overlap the pixel electrode 170. In such an exemplary embodiment, an area of the pixel electrode 170 may increase such that an aperture-ratio that may decrease due to the first shielding electrode 155 may not decrease in the present exemplary embodiment.

The first shielding electrode 155 includes the same material as that included in the gate electrode 153. For example, the first shielding electrode 155 may include an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), titanium (Ti), tantalum (Ta), or the like.

The first shielding electrode 155 may be grounded or receive a direct-current (DC) voltage that has a predetermined value. For example, the first shielding electrode 155 may receive a voltage having the same voltage level as that of a voltage applied to a common electrode 240, to be described below, or receive a voltage having the same voltage level as that of a voltage applied to a storage electrode (not illustrated).

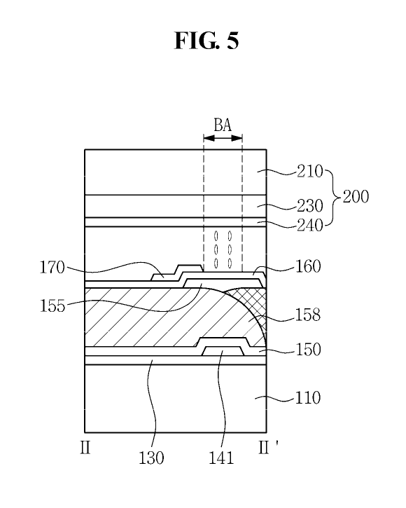

FIG. 5 is a cross-sectional view of an exemplary embodiment taken along line II-IP of FIG. 2.

Referring to FIG. 5, in the case that the first shielding electrode 155 receives a common voltage Vcom having the same voltage level as that of a voltage applied to the common electrode 240, light may not be transmitted through an area BA among the pixel electrodes 170 without using an additional light blocking member 220.

The second insulating layer 160 is disposed on the color filter 158, the gate wirings 151 and 153, and the first shielding electrode 155. The second insulating layer 160 may have a monolayer structure or a multilayer structure including, for example, silicon oxides, silicon nitrides, a photosensitive organic material, or a low dielectric constant insulating material such as a-Si:C:O or a-Si:O:F, for example.

The pixel electrode 170 is disposed on the second insulating layer 160. The pixel electrode 170 may be an electrode including a transparent conductor such as indium tin oxide (ITO) or indium zinc oxide (IZO). The pixel electrode 170 may be connected to the drain electrode 145 through a contact hole formed through the gate insulating layer 150, the color filter 158, and the second insulating layer 160.

In addition, since the pixel electrode 170 is disposed on a different layer from a layer on which the first shielding electrode 155 is disposed, the pixel electrode 170 may partially overlap an end portion of the first shielding electrode 155. In such an exemplary embodiment, an area of the pixel electrode 170 may increase such that an aperture-ratio that may decrease due to the first shielding electrode 155 may not decrease in the present exemplary embodiment.

A second shielding electrode 171 is disposed on the same layer as a layer on which the pixel electrode 170 is disposed. For example, the second shielding electrode 171 is disposed on the second insulating layer 160, extends substantially parallel to the gate line 151, and overlaps the gate line 151.

In addition, the second shielding electrode 171 may have a greater width than that of the gate line 151.

The second shielding electrode 171 includes the same material as that included in the pixel electrode 170. That is, the second shielding electrode 171 may be an electrode that includes a transparent conductor such as indium tin oxide (ITO) or indium zinc oxide (IZO).

The second shielding electrode 171 may be grounded or receive a DC voltage that has a predetermined value. For example, the second shielding electrode 171 may receive a voltage having the same voltage level as that of a voltage applied to the common electrode 240, to be described further below, or receive a voltage having the same voltage level as that of a voltage applied to a storage electrode (not illustrated).

In the case that the second shielding electrode 171 receives the voltage Vcom having the same voltage level as that of the voltage applied to the common electrode 240, light may not be transmitted through a predetermined portion without using an additional light blocking member 220.

Referring to FIGS. 2 and 3, an alignment layer (not illustrated) may be disposed on the pixel electrode 170. The alignment layer aligns liquid crystal molecules of the liquid crystal layer 300 so that a major axis of the liquid crystal molecules thereof is perpendicular to surfaces of the first panel 100 and the second panel 200 in the state that an electric field is absent between the first panel 100 and the second panel 200.

The second panel 200 includes a second substrate 210, the light blocking member 220, an overcoat layer 230, and the common electrode 240.

The second substrate 210 may be an insulating substrate, such as a plastic substrate, which has light transmitting characteristics and flexibility. However, exemplary embodiments are not limited thereto, and the second substrate 210 may include a hard substrate such as a glass substrate. That is, the second substrate 210 may include plastic or transparent glass such as soda lime glass or borosilicate glass, for example.

The light blocking member 220 is disposed on the second substrate 210. The light blocking member 220 may also be referred to as a black matrix, and may include a metal such as chromium oxide (CrOx) or an opaque organic-layer material. The light blocking member 220 may be omitted, and may be disposed on the first panel 100.

The overcoat layer 230 is disposed on the light blocking member 220. The overcoat layer 230 planarizes an uneven surface of a layer therebelow, e.g., the light blocking member 220, and significantly suppresses or prevents diffusion of undesired materials from the layer therebelow.

The common electrode 240 is disposed on the overcoat layer 230. According to an exemplary embodiment, the common electrode 240 may include a whole-plate electrode including a transparent conductor such as indium tin oxide (ITO) or indium zinc oxide (IZO). According to an alternative exemplary embodiment, the common electrode 240 may have a cross-shaped slit to define a plurality of domains.

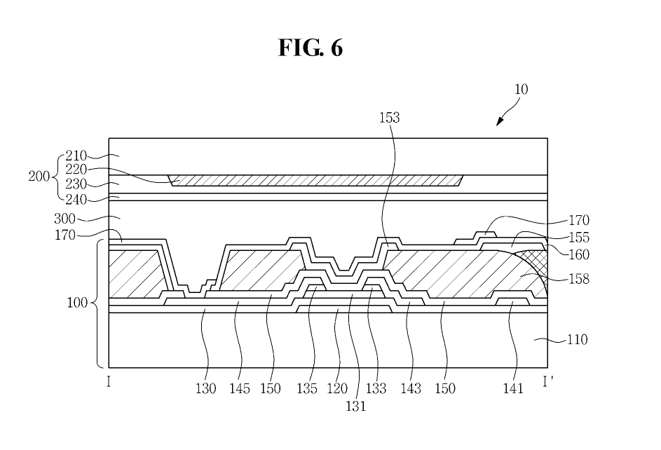

FIG. 6 is a cross-sectional view of still another exemplary embodiment taken along line I-I′ of FIG. 2. The descriptions described hereinabove with respect to an exemplary embodiment of the display device 10 will be omitted in descriptions with respect to another exemplary embodiment of the display device 10.

Referring to FIG. 6, another exemplary embodiment of the display device 10 includes a first panel 100 and a second panel 200 that oppose each other, and a liquid crystal layer 300 disposed between the first panel 100 and the second panel 200.

The first panel 100 includes a first substrate 110, a light blocking pattern 120 on the first substrate 110 and below a semiconductor layer 131, a first insulating layer 130, the semiconductor layer 131, data wirings 141, 143, and 145, a gate insulating layer 150, gate wirings 151 and 153, a first shielding electrode 155, a second insulating layer 160, and a pixel electrode 170.

Herein, the semiconductor layer 131 is disposed on the first insulating layer 130 to overlap the light blocking pattern 120. The light blocking pattern 120 may completely cover the semiconductor layer 131. The semiconductor layer 131 may include amorphous silicon (hereinafter, a-Si) or an oxide semiconductor including at least one selected from: gallium (Ga), indium (In), tin (Sn), and zinc (Zn).

Ohmic contact layers 133 and 135 are disposed on the semiconductor layer 131 and include a first ohmic contact layer 133 and a second ohmic contact layer 135. The first and second ohmic contact layers 133 and 135 oppose each other with a channel of the semiconductor layer 131 therebetween. At least one of the first and second ohmic contact layers 133 and 135 may include silicide or n+ hydrogenated amorphous silicon doped with n-type impurities, such as phosphorus (P), at high concentration. In the case that contact properties among the semiconductor layer 135 and the source electrode 143 and/or the drain electrode 145 are secured sufficiently, the first and second ohmic contact layers 133 and 135 of the present exemplary embodiment may be omitted.

The data wirings 141, 143, and 145 are disposed on the first insulating layer 130. The data wirings 141, 143, and 145 include a source electrode 143, a drain electrode 145, and a data line 141.

The source electrode 143 is disposed on the first ohmic contact layer 133 and the first insulating layer 130. The source electrode 143 and the data line 141 are unitary. The source electrode 143 and the data line 141 are formed of the same material and are formed through the same process. At least a portion of the source electrode 143 overlaps the semiconductor layer 131. The source electrode 143 may have one of an I-like shape, a C-like shape, and a U-like shape.

The drain electrode 145 is disposed on the second ohmic contact layer 135 and the first insulating layer 130. At least a portion of the drain electrode 145 overlaps the semiconductor layer 131. The drain electrode 145 is connected to the pixel electrode 170.

The data line 141 is disposed on the first insulating layer 130. The data line 141 extends in a first direction, e.g., a longitudinal direction, in a plan view and defines a pixel unit along with the gate line 151.

The gate insulating layer 150 is disposed on the first insulating layer 130, the semiconductor layer 131, and the data wirings 141, 143, and 145. The gate insulating layer 150 may include silicon oxides (SiOx) or silicon nitrides (SiNx). In addition, the gate insulating layer 150 may further include aluminum oxides, titanium oxides, tantalum oxides, or zirconium oxides.

A color filter 158 is disposed on the gate insulating layer 150. The color filter 158 may be one selected from a group consisting of a red color filter, a green color filter, a blue color filter, a cyan color filter, a magenta color filter, and a white color filter.

The gate wirings 151 and 153 are disposed on the gate insulating layer 150 and transmit a gate signal. The gate wirings 151 and 153 include a gate line 151 and a gate electrode 153.

In an exemplary embodiment, the color filter 158 is disposed between the gate insulating layer 150 and the gate electrode 153. In addition, the color filter 158 is disposed between the gate insulating layer 150 and the first shielding electrode 155 to be described below. The color filter 158 extends along a direction and is disposed on the first substrate 110. For example, the color filter 158 has a linear shape in a plan view and extends along the first direction, e.g., the longitudinal direction of the drawings. In addition, adjacent color filters 158 that are adjacent in a transverse direction in the drawings may overlap each other at border areas therebetween.

In an alternative exemplary embodiment, the color filter 158 may be disposed on the gate insulating layer 150 and the gate electrode 153. In addition, the color filter 158 may be disposed on the first shielding electrode 155 as disclosed in FIG. 4.

The gate line 151 extends in a second direction that intersects the data line 141 extending in the first direction. For example, the gate line 151 extends in the transverse direction in the drawings. The gate line 151 sequentially outputs gate signals in response to a gate control signal externally applied thereto. The gate signal includes a gate-on voltage Von that may turn on thin film transistors connected to a selected one of the gate lines 151 and a gate-off voltage Voff that may turn off thin film transistors connected to an unselected one of the gate lines 151. The gate electrode 153 protrudes from the gate line 151 to form a protrusion. The gate electrode 153, along with the source electrode 143 and the drain electrode 145, defines three terminals of the thin film transistor.

In addition, the gate electrode 153 is formed on the color filter 158 in a region corresponding to a hole formed through the color filter 158 and is disposed on the gate insulating layer 150 to overlap at least a portion of the semiconductor layer 131. That is, the color filter 158 has a hole exposing the gate insulating layer 150 and the gate electrode 153 is formed to cover the hole formed through the color filter 158.

The gate wirings 151 and 153 may include or be formed of an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), titanium (Ti), tantalum (Ta), or the like.

The first shielding electrode 155 is disposed on the same layer as a layer on which the gate line 151 is disposed and overlaps the data line 141. For example, the first shielding electrode 155 is disposed on the gate insulating layer 150 to be spaced apart from the gate line 151, extends substantially parallel to the data line 141, and overlaps the data line 141 so that a parasitic capacitance generated between the pixel electrode 170 and the data line 141, which may overlap the pixel electrode 170, may be significantly reduced.

The first shielding electrode 155 may have a greater width than that of the data line 141. In such an exemplary embodiment, an end portion of the first shielding electrode 155 may overlap the pixel electrode 170. In such an exemplary embodiment, an area of the pixel electrode 170 may increase such that an aperture-ratio that may decrease due to the first shielding electrode 155 may not decrease in the present exemplary embodiment.

The first shielding electrode 155 includes the same material as that included in the gate electrode 153. For example, the first shielding electrode 155 may include an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), titanium (Ti), tantalum (Ta), or the like.

The first shielding electrode 155 may be grounded or receive a DC voltage that has a predetermined value. For example, the first shielding electrode 155 may receive a voltage having the same voltage level as that of a voltage applied to a common electrode 240, to be described below, or receive a voltage having the same voltage level as that of a voltage applied to a storage electrode (not illustrated).

In the case that the first shielding electrode 155 receives a common voltage Vcom having the same voltage level as that of the voltage applied to the common electrode 240, light may not be transmitted through an area among the pixel electrodes 170 without using an additional light blocking member 220.

The second insulating layer 160 is disposed on the first shielding electrode 155. The second insulating layer 160 may have a monolayer structure or a multilayer structure including, for example, silicon oxides, silicon nitrides, a photosensitive organic material, or a low dielectric constant insulating material such as a-Si:C:O or a-Si:O:F, for example.

The pixel electrode 170 is disposed on the second insulating layer 160. The pixel electrode 170 may be an electrode including a transparent conductor such as indium tin oxide (ITO) or indium zinc oxide (IZO). The pixel electrode 170 may be connected to the drain electrode 145 through a contact hole formed through the gate insulating layer 150, the color filter 158, and the second insulating layer 160.

In addition, since the pixel electrode 170 is disposed on a different layer from a layer on which the first shielding electrode 155 is disposed, the pixel electrode 170 may partially overlap an end portion of the first shielding electrode 155. In such an exemplary embodiment, an area of the pixel electrode 170 may increase such that an aperture-ratio that may decrease due to the first shielding electrode 155 may not decrease in the present exemplary embodiment.

The second shielding electrode 171 is disposed on the same layer as a layer on which the pixel electrode 170 is disposed and overlaps the gate line 151. For example, the second shielding electrode 171 is disposed on the second insulating layer 160, extends substantially parallel to the gate line 151, and overlaps the gate line 151. In addition, the second shielding electrode 171 may have a greater width than that of the gate line 151.

The second shielding electrode 171 may include the same material as that included in the pixel electrode 170. That is, the second shielding electrode 171 may be an electrode including a transparent conductor such as indium tin oxide (ITO) or indium zinc oxide (IZO).

The second shielding electrode 171 may be grounded or receive a DC voltage that has a predetermined value. For example, the second shielding electrode 171 may receive a voltage having the same voltage level as that of the voltage applied to the common electrode 240, to be described below, or receive a voltage having the same voltage level as that of the voltage applied to the storage electrode (not illustrated).

In the case that the second shielding electrode 171 receives the voltage Vcom having the same voltage level as that of the voltage applied to the common electrode 240, light may not be transmitted through a predetermined portion without using an additional light blocking member 220.

An alignment layer (not illustrated) may be disposed on the pixel electrode 170. The alignment layer aligns liquid crystal molecules of the liquid crystal layer 300 so that a major axis of the liquid crystal molecules is perpendicular to surfaces of the first panel 100 and the second panel 200 in the state that an electric field is absent between the first panel 100 and the second panel 200.

As set forth above, according to one or more exemplary embodiments, the shielding electrode including the same material as a material included in the gate line is provided in the display device such that the parasitic capacitance generated between the pixel electrode and the data line may be reduced.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings. Various features of the above described and other embodiments can be mixed and matched in any manner, to produce further embodiments consistent with the inventive concept.

What is claimed is:

1. A display device comprising:
a substrate;
a data line disposed on the substrate, the data line extending in a first direction;
a gate insulating layer disposed on the data line;
a gate line disposed on the gate insulating layer, the gate line extending in a second direction intersecting the first direction;
a gate electrode protruding from the gate line;
a thin film transistor connected to the gate line and the data line; and
a first shielding electrode disposed on the same layer as a layer on which the gate line is disposed, the first shielding electrode overlapping the data line.

2. The display device as claimed in claim 1, wherein the first shielding electrode comprises the same material as a material included in the gate line.

3. The display device as claimed in claim 2, wherein the first shielding electrode has a greater width than a width of the data line.

4. The display device as claimed in claim 3, wherein the first shielding electrode completely covers the data line in a plan view.

5. The display device as claimed in claim 2, wherein the thin film transistor comprises:
a source electrode on the substrate, the source electrode extending from the data line;
a drain electrode spaced apart from the source electrode; and
a semiconductor layer between the source electrode and the drain electrode.

6. The display device as claimed in claim 5, wherein the semiconductor layer overlaps at least a portion of upper surfaces of the source electrode and the drain electrode.

7. The display device as claimed in claim 5, wherein the semiconductor layer is disposed on the source electrode and the drain electrode and overlaps at least a portion of the source electrode and the drain electrode.

8. The display device as claimed in claim 7, further comprising an ohmic contact layer disposed between the semiconductor layer and the source electrode or between the semiconductor and the drain electrode.

9. The display device as claimed in claim 5, further comprising a light blocking pattern disposed between the semiconductor layer and the substrate.

10. The display device as claimed in claim 2, further comprising a color filter on the gate insulating layer.

11. The display device as claimed in claim 10, wherein the color filter is disposed between the gate insulating layer and the gate electrode.

12. The display device as claimed in claim 10, wherein the color filter is disposed on the gate electrode.

13. The display device as claimed in claim 2, further comprising a pixel electrode connected to the thin film transistor, wherein an end portion of the first shielding electrode overlaps the pixel electrode.

14. The display device as claimed in claim 13, further comprising a second shielding electrode disposed on the same layer as a layer on which the pixel electrode is disposed, the second shielding electrode overlapping the gate line.

15. The display device as claimed in claim 14, wherein the second shielding electrode comprises the same material as that included in the pixel electrode.

16. The display device as claimed in claim 14, wherein the second shielding electrode has a greater width than a width of the gate line.

17. The display device as claimed in claim 16, wherein the second shielding electrode completely cover the gate line in a plan view.

18. A display device comprising:
a substrate;
a data line disposed on the substrate, the data line extending in a first direction;
a source electrode and a drain electrode disposed on the substrate;
a semiconductor layer disposed on the source electrode and the drain electrode to overlap the source electrode and the drain electrode;
a gate insulating layer disposed on the semiconductor layer;
a gate line disposed on the gate insulating layer, the gate line extending in a second direction intersecting the first direction;
a first shielding electrode disposed on the gate insulating layer, the first shielding electrode overlapping the data line and being disposed on the same layer as the gate line and being formed of the same material as the gate line; and
a pixel electrode connected to the drain electrode.

19. The display device as claimed in claim 18, further comprising a color filter disposed between the gate line and the gate insulating layer.

20. The display device as claimed in claim 18, further comprising a color filter disposed between the gate line and the pixel electrode.
